(19) United States
(12) Patent Application Publication
(10) Pub. No.: US 2003/0115502 A1
(43) Pub. Date: Jun. 19, 2003

(54) Method of restoring encapsulated integrated circuit devices

(75) Inventors: Timothy Calvin Visser, Grandville, MI (US); Gary M. Uhl, Grandville, MI (US)

Correspondence Address: VARNUM, RIDDERING, SCHMIDT & HOWLETT LLP, P.O. BOX 352, GRAND RAPIDS, MI, 49501, US

(73) Assignee: Smiths Industries Aerospace & Defense Systems, Inc.

(21) Appl. No.: 10/020,628

(22) Filed: Dec. 14, 2001

(51) Int. Cl. H04L 1/22

(52) U.S. Cl. 714/22

(57) ABSTRACT

A method for restoring integrated circuit devices in an encapsulated array of integrated circuit devices includes the steps of testing the array and applying a voltage signal to pins appearing to be disconnected from an element internal to the array.

### CROSS-REFERENCE TO RELATED APPLICATIONS

Not applicable.

### STATEMENT REGARDING FEDERALLY SPONSORED RESEARCH OR DEVELOPMENT

Not applicable.

### REFERENCE TO A MICROFISHE APPENDIX

Not applicable.

### BACKGROUND OF THE INVENTION

1. Field of the Invention

The invention relates to integrated circuits and more particularly to restoring plastic encapsulated integrated circuit memory devices after high temperature exposure.

2. Background Art

Integrated circuit devices are widely used in a variety of electronic logic circuits and memory circuits and, to allow for handling and to protect against damage, the devices are typically encapsulated in a plastic material. As the device manufacturing techniques and the circuits in which the devices are used have become more sophisticated, the devices are encapsulated in ever-greater circuit densities in a single encapsulation unit. There has been a migration to finer and finer design rules for integrated circuits resulting in increased sensitivity to the effects of surface charges and of charges exterior to the encapsulation.

Integrated circuit memory devices are commonly used in large assemblies such as integrated circuit memories, including crash protected memories used in aircraft and elsewhere. Such crash protected memories are used for recording data representative of the status of a number of critical instruments, control levers and the like, for after crash analysis. As aircraft instrumentation becomes more sophisticated, there is a demand for more and more memory space to store data indicative of the states of various critical devices, for after-crash analysis. However, the cost of increasing the physical size of the protective housing is high. Accordingly, it is desirable to use higher density memory devices, such as the commercially available plastic encapsulated electronic memory arrays, commonly referred to a PEM devices.

Plastic encapsulated memory devices have certain properties that make such devices suitable for use in crash protected memories. In addition to being able to withstand the shock of a crash, a crash protected memory must also be able to withstand high temperatures, e.g. 300 C., for an extended period of time, e,g. 1 hour, or +260° C. for 10 hours. It has been observed, however, that failure rates of devices in encapsulated circuit arrays, such as electronic memory arrays, tend to increase after high temperature exposures. This phenomenon has been described in published literature, for example in a publication entitled “THE EFFECTS OF MATERIALS AND POSTMOLD PROFILES ON ENCAPSULATED INTEGRATED CIRCUITS”, by R. D. Mosbarger, et al. 1994 IEEE/RPS. The publication describes various failure modes of these devices. It is noted in that publication, that the cause of the failures was found to be a forward biased enhancement mode parasitic field effect transistor with an accumulated charge, providing an extraneous electric field and yielding an inoperative device after high temperature exposures. Hence, such devices would appear to be unsuitable for use in crash-protected memories that have to be able to withstand temperatures on the order of +260° C.

### SUMMARY OF THE INVENTION

These and other problems of the prior art are solved in accordance with the present invention, by a method for restoring faulty devices in an encapsulated array thereby making such devices suitable for high-temperature applications. A method of treating PEM devices to make such devices suitable for high-temperature applications includes the steps of testing the array, identifying a faulty device within the array, and applying a voltage signal of a predetermined level to terminals of the encapsulated array connected to the identified faulty device.

Advantageously, after application of a voltage signal in accordance with the method of this invention, plastic encapsulated memory do not manifest the problems outlined above after further exposure to elevated temperatures.

### BRIEF DESCRIPTION OF THE SEVERAL VIEWS OF THE DRAWINGS

Not applicable.

### DETAILED DESCRIPTION OF THE METHOD

A method for recovering data from an electronically programmable memory includes placing the memory device in a commonly known and commercially available device programmer. The programmer may, for example be a device such as the BP-1400 Universal Device Programmer sold by BP Microsystems or the like. The method further includes the steps of:

Straightening and cleaning all component lead, preferably using tweezers and isopropyl alcohol, or similar device;

Placing the memory unit in a device programmer such as the well known BP-1400 Universal Device Programmer or similar device;

Executing a “Read” command in test device.

In the event of a read error, the device programmer will typically provides an error message when indicating that the device can not be read. The error message preferably identifies the specific connecting pins of the device under tests that do not appear to have a proper connection internal to the encapsulated device.

The method of the invention further includes the step of applying a negative voltage signal to each connecting pin identified by the test equipment as not having a proper connection. In one application of the method of the invention, a signal of negative five volts is applied to the identified pins, through a resistor, for a specified period of time. In a particular application, a current limited, negative five volts signal is applied to the identified pins, preferably through a 100K ohm resistor. The voltage is applied through the resistor for a period of approximately 100 milliseconds.

It is noted that all leads of a memory unit to be tested are preferably cleaned with a cleaning solution, such as isopropyl alcohol, before connecting signal generating equipment to the pins.

In an illustrative embodiment of the invention, the equipment used for applying the signal to the device pins for the prescribed period of time is a series MT-3 curve trace system sold by UltraTest International of San Jose, Calif. Other suitable equipment may also be used to apply an appropriate voltage to the pins for an appropriate period of time.

It is noted that all leads of a memory unit to be tested are preferably cleaned with a cleaning solution, such as isopropyl alcohol, before connecting signal generating equipment to the pins.

In a preferred embodiment of the invention, the method includes the further step of placing the device under test in a programmer again, after the step of applying the appropriate signal to the identified pins, and executing the “Read” command again. The further step is preferably executed in order to determine whether all errors have been properly corrected. In the event that further errors are found, the steps of the method outlined above are repeated.

1. A method of restoring faulty connections in an integrated circuit device having a plurality of memory circuit elements and a plurality of connecting pins connected to said memory circuit elements, the method comprising the steps of:
using an integrated circuit programming device, executing a device read command;
obtaining an error message from said programming device identifying certain of said connecting pins appearing to be disconnected from a memory circuit element; and
applying a voltage signal to said certain of said connecting pins.

2. The method in accordance with claim 1 wherein said signal comprises a read command for reading said memory device.

3. The method in accordance with claim 1 wherein said step of applying comprises applying said signal to said certain connecting pins through a resistor.

4. The method in accordance with claim 3 wherein said signal has value of at least 5 volts.

5. The method in accordance with claim 4 wherein said signal has value of negative five volts.

6. The method in accordance with claim 5 wherein said resistor has a value of 100 kilo-ohms.

7. A method of restoring faulty elements internal to an integrated circuit device having at least one external connecting pin, said method comprising the step of applying a voltage signal of a predefined level said external connecting pin.
